(19) United States
(12) Patent Application Publication
(10) Pub. No.: US 2019/0333787 A1
(43) Pub. Date: Oct. 31, 2019

(54) SUBSTRATE SUPPORT ELEMENT FOR A SUPPORT RACK

(71) Applicant: Heraeus Noblelight GmbH, Hanau (DE)

(72) Inventors: Thomas PIELA, Hanau (DE); Larissa VON RIEWEL, Bergisch Gladbach (DE)

(21) Appl. No.: 16/309,434

(22) PCT Filed: May 22, 2017
(86) PCT No.: PCT/EP2017/062289

§ 371 Date: Dec. 12, 2018

(30) Foreign Application Priority Data
Jun. 20, 2016 (DE) 10 2016 111 236.4

(51) Int. Cl. H01L 21/67; H01L 21/673

(52) U.S. Cl. CPC H01L 21/67103; H01L 21/67306; H01L 21/67115

(57) ABSTRACT

A substrate support element for a support rack for thermal treatment of a substrate is provided. The substrate support element includes a support surface for the substrate. The substrate support element is a composite body that includes a first composite component and a second composite component, whereby the first composite component has a thermal conductivity in the range of 0.5 to 40 W/(m·K) and the second composite component has a thermal conductivity in the range of 70 to 450 W/(m·K).

### CROSS REFERENCE TO RELATED APPLICATIONS

This application is a U.S. National Phase filing of international patent application number PCT/EP2017/062289 filed May 22, 2017 that claims the priority of German patent application number 102016111236.4 filed Jun. 20, 2016. The disclosures of these applications are hereby incorporated by reference in their entirety.

### FIELD

The invention relates to a substrate support element for a support rack for thermal treatment of a substrate, including a support surface for the substrate.

### BACKGROUND

During the production and processing of silicon wafers, the silicon wafer is periodically subjected to a thermal treatment. In most cases, infrared emitters are used as an energy source for the thermal treatment.

Silicon wafers are thin disk-shaped substrates that include a top side and a bottom side. A good homogeneous thermal treatment of the substrates may be attained if the infrared emitters are allocated to the top and/or bottom side of the substrate. This requires a comparably large construction space to be present above and/or below the wafer to be irradiated.

Higher throughput in the thermal treatment of the wafers is attained, if the wafers are arranged in a support rack that is fed to the thermal treatment fully configured with the wafers.

Support racks of this type are often vertical racks; they essentially consist of a top and a bottom limiting plate that are connected to each other by means of multiple slitted crossbars. During the processing of wafers with semiconductor technology, the support racks are used in a furnace, a coating or etching facility, but also for transport and storage of the wafers. A support rack of this type is known, for example, from DE 20 2005 001 721 U1.

However, the support racks are disadvantageous in that there remains only a small amount of assembly space between the wafers bracketed in the support rack, which leads to the infrared emitters being arranged to the side of the support rack. An arrangement of this type results in the wafer edges having to be irradiated more strongly as compared to the middle of the wafer. Inhomogeneous irradiation of the wafers can impair the quality of the wafers. Moreover, the irradiation process time is dependent on the time it takes for the wafer—including its mid area—to attain the selected temperature. Thus, the radiation of the wafers from the side is therefore also associated with a longer irradiation process time.

Moreover, support racks including multiple levels, such as are used in a shelf system, are also known. In these support racks, one or more substrates (wafers) are placed on each of the individual levels. Support racks of this type can be provided as a one-part or multi-part design. For example, multiple support elements, each forming a separate level, may be held together in a holding frame. In support racks of the type of a shelf system, the heat supply takes place by means of two mechanisms, namely, on the one hand, directly by irradiation of the substrate and, on the other hand, indirectly by heat transfer from the respective shelf level. However, the use of shelf like racks is also associated with a problem, as a matter of rule, in that the infrared emitters need to be arranged to the side adjacent to the rack, which often leads to inhomogeneous distribution of the substrate temperature.

### SUMMARY

In accordance with certain exemplary embodiments of the invention a substrate support element is provided for a substrate rack that allows for a substrate to be heated as homogeneously as possible.

Moreover, exemplar embodiments of the invention have an object to devise a support rack and/or an irradiation facility that allow for a substrate to be heated as homogeneously as possible.

According to an exemplary embodiment of the invention, a substrate support element for a support rack for thermal treatment of a substrate is provided. The substrate support element includes a composite body that includes a first composite component and a second composite component. The first composite component has a thermal conductivity in the range of 0.5 to 40 W/(m·K) and the second composite component has a thermal conductivity in the range of 70 to 450 W/(m·K). The composite body includes a support surface for the substrate.

According to another exemplary embodiment of the invention, a support rack for thermal treatment of a substrate is provided. The support rack includes a first substrate support element. The first substrate support element includes a first composite body, the first composite body including a first composite component and a second composite component. The first composite component has a thermal conductivity in the range of 0.5 to 40 W/(m·K) and the second composite component has a thermal conductivity in the range of 70 to 450 W/(m·K). The first composite body includes a first substrate support surface. The support rack also includes a second substrate support element. The second substrate support element includes a second composite body, the second composite body including a third composite component and a fourth composite component. The third composite component has a thermal conductivity in the range of 0.5 to 40 W/(m·K) and the fourth composite component has a thermal conductivity in the range of 70 to 450 W/(m·K). The second composite body includes a second substrate support surface. The first substrate support element and the second substrate support element are arranged such that the first substrate support surface and the second substrate support surface extend parallel with respect to each other. The first composite component and the third composite component may, or may not, be formed from the same material. The second composite component and the fourth composite component may, or may not, be formed from the same material.

According to yet another exemplary embodiment of the invention, a device for irradiation of a substrate is provided. The device includes at least one substrate support element. The at least one substrate support element includes a composite body. The composite body includes a first composite component and a second composite component. The first composite component has a thermal conductivity in the range of 0.5 to 40 W/(m·K) and the second composite component has a thermal conductivity in the range of 70 to 450 W/(m·K). The composite body includes a support surface for the substrate. The device also includes at least one infrared emitter for irradiation of the at least one substrate support element.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 illustrates a support rack for thermal treatment of a substrate, in which multiple substrate support elements are stacked in the way of a shelf system, in accordance with an exemplary embodiment of the invention;

FIG. 2 is a sectional view of a device for irradiation of a substrate in accordance with an exemplary embodiment of the invention;

FIG. 3 is a temperature distribution diagram depicting the surface temperature of a silicon substrate on a support surface made of carbon, as well as a schematic view, for illustration of the temperature distribution;

FIG. 4 is a temperature distribution diagram depicting the surface temperature of a silicon substrate on a support surface made of aluminum, as well as a schematic view, for illustration of the temperature distribution;

FIG. 5 is a top view of various substrate support elements in accordance with various exemplary embodiments of the invention; and

FIG. 6 is a top view (A), and a sectional view (B), of a substrate support element in accordance with an exemplary embodiment of the invention.

### DETAILED DESCRIPTION

Exemplary embodiments of the invention relate to a substrate support element for a support rack for thermal treatment of a substrate, including a support surface for the substrate. Moreover, exemplary aspects of invention relate to a support rack for thermal treatment of a substrate, as well as a device for irradiation of a substrate.

Support racks in accordance with certain exemplary embodiments of the invention are used for bracketing multiple substrates, for example, for bracketing semiconductor disks (wafers). A common application of support racks is the thermal treatment of silicon wafers in the semiconductor or photovoltaics industry. Known support racks include multiple substrate support elements onto which one substrate each can be placed. For this purpose, the substrate support elements are frequently equipped with a support surface, for example, in the form of a depression.

In accordance with exemplary embodiments of the invention related to a substrate support element, the substrate support element may be a composite body that includes a first composite component and a second composite component, whereby the first composite component has a thermal conductivity in the range of 0.5 to 40 W/(m·K) and the second composite component has a thermal conductivity in the range of 70 to 450 W/(m·K).

Substrate support elements that are used for thermal treatment of substrates are typically manufactured from a single homogeneous material that is essentially characterized by its good temperature stability and good chemical resistance. In particular in semiconductor production, the yield and the electrical performance of semiconductor components is essentially governed by the extent to which it is possible to prevent contamination of the semiconductor material by impurities during the production of the semiconductor. Such contaminations can be caused, for example, by the apparatus used in the process.

Lateral irradiation of conventional substrate support elements manufactured from a single material is often observed to be associated with temperature differences in a substrate placed on the substrate support elements. This is because the substrate support elements include an edge area and a middle area, whereby the edge area of the substrate support element facing the radiation source is heated more strongly than, for example, the middle area. The attendant temperature differences of the substrate support element are also reflected in the substrate temperature.

According to certain exemplary embodiments of the invention, the substrate support element is a composite body that includes at least two composite components that differ in their thermal conductivity. In this context, a first composite component has a thermal conductivity in the range of 0.5 to 40 W/(m·K) and a second composite component has a thermal conductivity in the range of 70 to 450 W/(m·K).

The thermal conductivity, also called the coefficient of thermal conductivity, is understood to be a substance-specific physical parameter; it is a measure of the heat transfer by heat conduction within a material. The existence of a temperature difference is a prerequisite for heat conduction. Metals usually have a good thermal conductivity based on heat energy being transported well in metals by means of the conducting electrons. Table 1 below lists thermal conductivities of some materials in an exemplary manner.

TABLE 1

| | Thermal | | Thermal |
|---|---|---|---|
| | conductivity λ | | conductivity λ |
| Substance | [W/(m · K)] | Substance | [W/(m · K)] |
| Silver | 419 | Aluminum oxide | 25-39 |
| Copper | 372 | Graphite | 5-17 |
| Gold | 308 | Quartz | 1.1 |
| Aluminum | 209 | Glass | 0.6-1.0 |
| Platinum | 70 | | |

To attain a temperature distribution on the substrate that is as homogeneous as possible, the composite compounds are selected appropriately such that they act towards a temperature balance.

In a simple case, areas of the substrate support element that are exposed to comparably high irradiation intensities and for which a high temperature is expected are manufactured from the first composite component, while areas that are exposed to comparably low irradiation intensities and for which a low temperature is expected are manufactured from the second composite component.

Due to areas of the substrate support element for which a low temperature is expected being manufactured from the second composite component, which has a higher thermal conductivity, the heat energy can be transported easily into these areas and can be distributed homogeneously in these areas, for example, from the edge area to the middle area. The areas of the substrate support element manufactured from the first composite component are exposed to a high energy input, but the direct transfer of the energy is counteracted by the low thermal conductivity of the first composite component. Since the substrate support element, according to certain embodiments of the invention, is a composite body, the second composite component can distribute the heat energy introduced into the first composite component as homogeneously as possible to the entire substrate support element, whereby the occurrence of high temperature areas on the substrate is simultaneously reduced.

The substance properties and the geometry of the composite components are of import for the properties of the composite body. In particular size effects play a role. The first and second composite components are connected in a material-bonded manner, or by form-fit, or a combination of the two. Since the size, shape and number of the support surface areas that are manufactured from the first and/or the second composite component depend on the type of irradiation, in particular on the irradiation power, the distance from the radiation source and the substrate to be irradiated, it is advantageous for these to be regularly adapted to the irradiation situation.

A preferred refinement of the substrate support element according to exemplary aspects of the invention provides the support surface to be manufactured from the second composite component and provides an edge area manufactured from the first composite component to be adjacent to the support surface.

A support surface that is manufactured from the second composite component contributes to a homogeneous substrate temperature due to its good thermal conductivity. Since the support surface is surrounded, at least in part, by an edge area manufactured from the first composite component, heat energy introduced into the substrate support element—for example on the side thereof—is initially stored in the edge area due to the comparably low thermal conductivity of the first composite component, and is then transported away in the direction of the support surface by means of the second composite component in order to be distributed homogeneously there.

The support surface can be surrounded by the edge area completely or in part. In a simple case, the edge area is allocated only to one side that is exposed directly to a heat input, for example, to the side of the substrate support element that faces a radiation source.

An edge area that surrounds the support surface completely has proven to be just as advantageous. In this case, the edge area serves as an energy store by means of which energy is stored and is made available uniformly for heating of the support surface. The energy transport is provided for by the support surface, which is made from the second composite component. It has proven to be particularly expedient in this context to have the support surface be formed by a disk-shaped support element made of the second composite component that includes a top side and a bottom side, and to have the edge area overlap, at least in part, with the top side and/or the bottom side of the support element. Due to the overlapping of the edge area and the support element, the contact area between the first and second composite components is enlarged such that a particularly efficient heat transfer from the first to the second composite component is made possible.

In another refinement of the substrate support element according to exemplary aspects of the invention, the support surface includes the first and the second composite components.

Conventional substrate support elements are manufactured from a single material such that the support surface consists of the same material as the support element. A substrate supported on it usually shows temperature differences upon irradiation. In this context, in particular the side of the substrate and of the substrate support element facing the radiation source is/are heated more strongly than, for example, the middle area thereof.

In contrast, it has proven to be particularly expedient to provide a modified support surface in the substrate support element according to exemplary aspects of the invention, whereby the physical properties of the modified support surface are adapted to the lateral irradiation of the support surface and of a substrate possibly placed on it.

In a simple case, an area of the support surface for which a low corresponding substrate temperature is expected is manufactured from the second composite component having a higher thermal conductivity. This often applies, for example, to the middle area of the support surface. If the support surface has a good thermal conductivity in this area, heat energy can be transported easily into this area and can be distributed homogeneously in this area, for example, from an edge area into the middle area. Preferably, areas of the support surface that are expected to be heated more strongly due to their position relative to the radiation source are manufactured from the first composite component. These areas are still exposed to a higher energy input, but transfer of the energy is counteracted by the low thermal conductivity. By this means, the surface area of high temperature areas on the substrate is minimized.

According to certain exemplary embodiments of the invention, it has proven to be particularly expedient for the first composite component to have a specific heat capacity at 20° C. of at least 0.7 kJ/(kg·K), preferably to have a specific heat capacity at 20° C. in the range of 0.7 kJ/(kg·K) to 1.0 kJ/(kg·K).

The specific heat capacity of a substance is a measure for which amount of heat a given amount of a substance can take up upon a temperature change by 1 K, i.e. the degree to which the substance can take up and store heat energy. If the first composite component has a heat capacity of at least 0.7 kJ/(kg·K), it can take up a comparably large amount of heat energy. This reduces the amount of energy that is taken up by a substrate that is possibly placed on it. Accordingly, the larger the heat capacity of the first composite component, the lower is the amount of heat that can be taken up by the substrate and, accordingly, the lower is the substrate temperature.

According to certain exemplary embodiments of the invention, the first composite component is allocated to an area of the support surface for which a high corresponding substrate temperature is expected, for example, an edge area of the support surface. In combination with a suitable selection of the composite components based on their thermal conductivity, the use of a composite component with a heat capacity in the range specified above makes an additional contribution to balancing out differences in substrate temperature.

Table 2 below lists the specific heat capacities of some materials at T=20° C. in exemplary manner.

TABLE 2

| | specific | | specific |
|---|---|---|---|
| | heat capacity | | heat capacity |
| Substance | [kJ/(kg · K)] | Substance | [kJ/(kg · K)] |
| Silver | 0.234 | Aluminum oxide | 0.9 |
| Copper | 0.385 | Graphite | 0.715 |
| Gold | 0.13 | Quartz glass | 0.729 |
| Aluminum | 0.896 | Glass | 0.779 |
| Platinum | 0.134 | | |

A refinement of the substrate support element according to exemplary aspects of the invention provides the mass of the first composite component and the mass of the second composite component of the support surface to be matched to each other appropriately such that the heat capacity of the first composite component is larger than the heat capacity of the second component.

The heat capacity of the composite components depends, inter alia, on their mass. The larger the mass of a composite component, the larger is its heat capacity. Moreover, the heat capacity of the composite component has an impact on the temperature distribution in a substrate that is placed on the support surface and is irradiated with infrared radiation. The heat capacity of a composite component shall be understood to be the ratio of the supplied amount of heat and the heating thus attained. The larger the heat capacity, the more energy needs to be supplied to the composite component to heat it by 1 K. According to certain exemplary embodiments of the invention, the first composite component is preferably allocated to areas of the support surface for which a higher corresponding substrate temperature is expected. If the heat capacity of the first composite component is larger than the heat capacity of the second composite component, areas with the first composite component are heated less strongly. In contrast, areas with the second composite component are heated more strongly. This contributes to a balancing out of differences in substrate temperature. In this context, it has proven to be expedient to have the heat capacity of the first composite component be at least 30% larger than the heat capacity of the second composite component. For example, the support surface may be provided as a level surface.

A level surface can be produced by a low production effort, for example, by grinding. In addition, it is advantageous in that a substrate, also being level, includes a largest possible contact area with the support surface. This contributes to the amount of heat being distributed over the substrate by the contact surface as homogeneously as possible.

A substrate placed on the support surface can rest on the support surface either fully or in part. Preferably, a substrate placed on the support surface rests fully on the support surface by means of its contact side. This is advantageous in that the temperature of the contact side can be adjusted via the support surface as much as possible such that a heating of the substrate that is as homogeneous as possible is made possible.

Exemplary ranges for the size of the support surface for the substrate is: in the range of 10,000 mm² to 160,000 mm²; and in the range of 10,000 mm² to 15,000 mm².

The larger the support surface, the more difficult it is to make the support surface have a homogeneous temperature. A support surface in the range of 10,000 mm² to 160,000 mm² is sufficiently large for accommodation of common substrates, such as, for example, semiconductor wafers. At the same time, the temperature of the support surface can be kept sufficiently homogeneous. Moreover, a support surface of more than 160,000 mm² is difficult to manufacture.

In certain exemplary embodiments of the invention, it has proven to be particularly expedient for the size of the support surface to be in the range of 10,000 mm² to 15,000 mm². A support surface in this range is suitable, in particular, for accommodation of wafers of the type used in the production of electronic components, for example, in the production of integrated circuits. In this context, it has proven to be expedient for the support surface to be square or round in shape. Referring to a square support surface, the size thereof may be, for example, between 100 mm×100 mm and 122 mm×122 mm; the support surface diameter of a round support surface may be, for example, between 56 mm and 120 mm.

In certain exemplary embodiments of the invention, it has proven to be expedient for the support surface to have a first zone including the first composite component and a second zone including the second composite component.

The term, zone, shall be understood to mean an area of the support surface that consist exclusively of the first composite component. In the simplest case, the first zone and the second zone are immediately adjacent to each other. However, they can just as well be situated at a distance from each other. The use of zones is advantageous in that these can be manufactured easily and inexpensively and can be connected to each other. The connection of first and second zones may be accomplished by means of, for example, a form-fit, or in material-bonded manner (e.g., by welding or gluing). A combination of form-fit and material-bonded connection is feasible as well. A solely form-fit connection is advantageous in that it is particularly easy to produce.

Advantageously, the first zone includes a section that is oval in shape.

The temperature distribution pattern on a disk-shaped level substrate often includes isotherms with an oval shape section. It has therefore been expedient to have the first zone be adapted to the shape of the isotherms. For example, the second zone also includes a section that is oval in shape. In certain exemplary embodiments of the invention, it is particularly expedient for the first and second zones to be immediately adjacent to each other and for the first zone to include an oval shape section and the second zone to include a second oval shape section that corresponds to the first shape section.

In a refinement of the substrate support element according to certain exemplary aspects of the invention, the first composite component is carbon, silicon carbide or blackened zirconium oxide.

The materials specified above have not only good thermal conductivity in the range specified above, but also good temperature stability and good chemical stability.

In this context, it has been expedient for the second composite component to contain a metal, such as, for example, aluminum or an alloy thereof, or high-temperature resistant steel.

Metals usually have a good thermal conductivity based on the fact that heat energy can be transported in metals by means of their conducting electrons. In particular, aluminum shows sufficient chemical stability at elevated temperatures and is therefore well-suited for use as composite component.

Advantageously, the substrate support element can be used in a known support rack for thermal treatment of a semiconductor wafer.

Referring to the support rack for thermal treatment of a substrate, the object specified above is solved according to certain exemplary embodiments of the invention based on a support rack of the type specified above in that it includes a first substrate support element and a second substrate support element, whereby the first and second substrate support elements are arranged appropriately such that their respective support surfaces for the substrate extend parallel to each other.

The support rack according to certain exemplary embodiments of the invention is designed, in particular, for thermal treatment of a semiconductor disk (silicon wafer). Support surfaces of the substrate support elements are arranged parallel with respect to each other in this context. For example, first and second support elements are arranged in the way of shelves designed to accommodate substrates. The use of the shelves-like support rack is advantageous in that the energy required for heating can be provided by two mechanisms, namely, on the one hand, directly by direct irradiation of the substrate and, on the other hand, indirectly by heat conduction by means of the support rack itself, which also heats up during the irradiation process. The support rack can have a one-part or multi-part design. It includes at least two substrate support elements.

The support surface of conventional substrate support elements usually consist of the same material as the support element. In contrast, the support rack according to certain exemplary embodiments of the invention is provided with support elements in the form of a composite body that includes at least two composite components that have different thermal conductivities. In this context, the first composite component has a thermal conductivity in the range of 0.5 to 40 W/(m·K) and the second composite component has a thermal conductivity in the range of 70 to 450 W/(m·K).

As explained above, the composite components are selected appropriately such that they act towards a temperature balance. By this means, a temperature distribution on the substrate that is as homogeneous as possible is obtained.

Referring to the device for irradiation of a substrate, the object specified above is solved according to certain exemplary embodiments of the invention in that the device includes at least one substrate support element and at least one infrared emitter for irradiation of the substrate support element.

A device of this type is well-suited for irradiation of a semiconductor disk (silicon wafer); it includes at least one infrared radiation source and can be used for thermal treatment of a substance. The infrared emitter is designed for irradiation of the substrate support element, in particular of the support surface and of a substrate placed thereon. The infrared emitter may include, for example, a longitudinal axis that extends perpendicular parallel or diagonal to the support surface of the substrate support element.

The device includes at least one substrate carrier element in the scope of the invention that is provided with a modified support surface. The support surface includes at least two composite components that have different thermal conductivities. In this context, the first composite component has a thermal conductivity in the range of 0.5 to 40 W/(m·K) and the second composite component has a thermal conductivity in the range of 70 to 450 W/(m·K). The physical properties of the composite components are adapted to the lateral irradiation of the support surface and of a substrate that is possibly placed thereon.

To attain a temperature distribution on the substrate that is as homogeneous as possible, the composite compounds are selected appropriately such that they act towards a temperature balance. In a simple case, an area of the support surface for which a low corresponding substrate temperature is expected is manufactured from the second composite component having a higher thermal conductivity. This often applies, for example, to the middle area of the support surface. If the support surface has a good thermal conductivity in this area, heat energy can be transported easily into this area and can be distributed homogeneously in this area, for example, from an edge area into the middle area. For example, areas of the support surface that are expected to be heated more strongly due to their position relative to the radiation source are manufactured from the first composite component. These areas are still exposed to a higher energy input, but transfer of the energy is counteracted by the low thermal conductivity. By this means, the size of high temperature areas on the substrate is minimized and heating of the substrate as homogeneously as possible is facilitated.

In this context, it has proven to be expedient for the support surface of the substrate support element to have a first zone including the first composite component and a second zone including the second composite component, and to have a transverse side facing the infrared emitter as well as two longitudinal sides, whereby the first zone extends along the transverse side.

The transverse side is regularly allocated to the infrared emitter; it is therefore exposed to the highest irradiation intensities. It has the shortest distance from the infrared emitter. A first zone extending along the transverse side contributes to the temperature in the region of the transverse side being kept as low as possible and a spreading of areas of high temperature being counteracted.

In this context, it has proven to be particular advantageous for the second zone to extend along at least one of the longitudinal sides.

The temperature of the substrate is periodically higher on the longitudinal sides than in the middle of the substrate. This is related to a substrate usually heating up more rapidly on its edges than in the middle. The second zone extending along at least one, preferably along both, longitudinal sides allows the heat to be transferred from the edges into the middle. For this purpose, the second zone is made from the second composite component, which contributes to a rapid temperature balance within the substrate due to its high thermal conductivity.

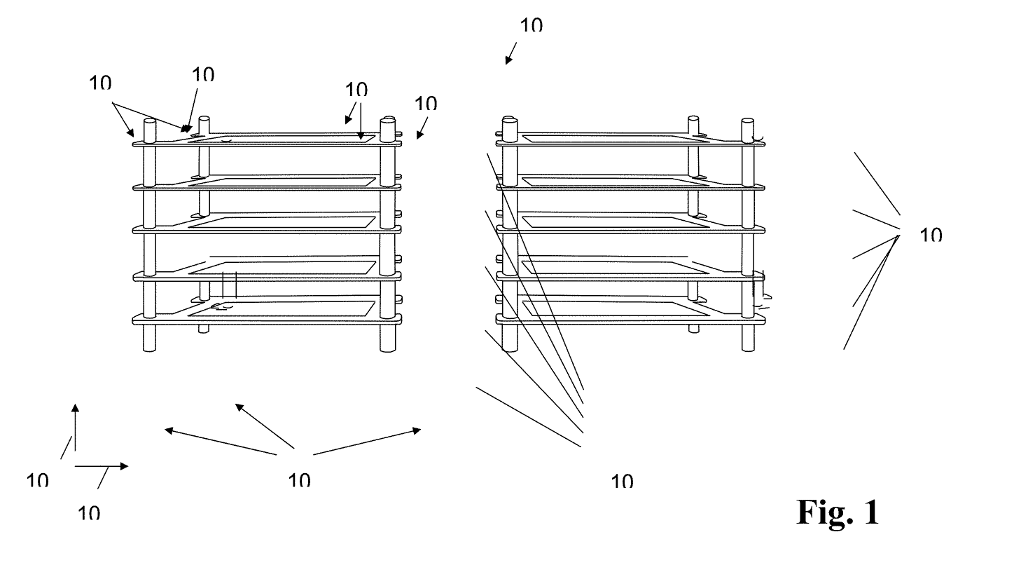

Referring now to the drawings, FIG. 1 is a perspective view of an embodiment of the support rack according to certain exemplary embodiments of the invention, which, in toto, has reference number 100 assigned to it. The support rack 100 is designed for thermal treatment of silicon wafers in the semiconductor/photovoltaics industry. The support racks in the way of shelves are also referred to as “stacks” in English-speaking countries. The support rack 100 includes multiple substrate support elements 101. For simplification of the presentation, FIG. 1 shows an arrangement of ten substrate support elements 101 for exemplary purposes. The substrate support elements 101 are identical in design. The support rack 100 includes five substrate support elements 101 stacked on each other in vertical direction 103. Moreover, the support rack 100 extends in horizontal direction 102; here, two substrate support elements 101 are arranged adjacent to each other in each level.

One of the substrate support elements 101 shall be illustrated in more detail in the following for exemplary purposes.

The substrate support element 101 is made from carbon; it includes two longitudinal sides 105 and two transverse sides 104. The transverse sides 104 have two projections 106 each situated on them, by means of which the substrate support element 101 can be attached to the crossbars 107. The cylinder-shaped crossbars 107 are made of steel and are each provided with an external thread. The substrate support element 101 includes corresponding boreholes with an internal thread such that the substrate support element 101 can be screwed to the crossbars 107. The thread diameter is 8 mm. The crossbars 107 have a circular radial cross-section, the diameter of the crossbars is 8 mm.

The substrate support element 101 has a length of 200 mm (corresponding to the longitudinal side 105 including the projections 106 with a projection length of 30 mm) and a width of 150 mm (corresponding to a transverse side 104). The substrate support element 101 is 2 mm in thickness. A support surface 108 for a semiconductor disk is provided on the top side of the substrate support element 101 in the form of a rectangular depression.

In the area of the support surface 108, the substrate support element 101 is made from two composite components, namely from the first composite component carbon (thermal conductivity: 17 W/(m·K)) and the second composite component aluminum (thermal conductivity: 209 W/(m·K)); it is dimensioned appropriately such that a silicon wafer possibly placed on the support surface 108 fully contacts the support surface by its bottom side.

The support surface 108 is rectangular in shape and has a length of 101 mm and a width of 101 mm.

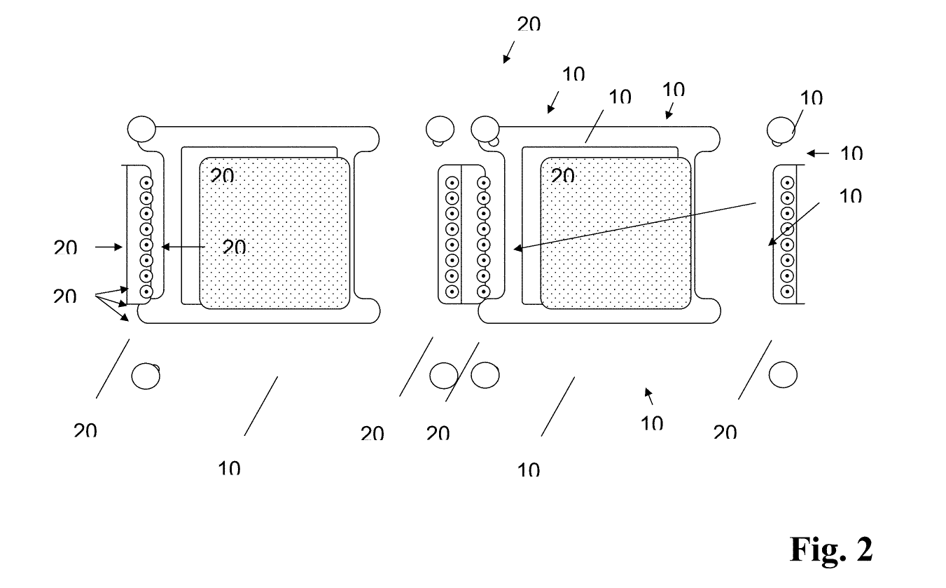

FIG. 2 shows a sectional view of a device according to certain exemplary embodiments of the invention for irradiation of semiconductor disks, which, in toto, has reference number 200 assigned to it. The device 200 includes four infrared emitter modules 201, 202, 203, 204, as well as a support rack 100 of the type described in FIG. 1.

In as far as the same reference numbers are used in FIG. 2 as in FIG. 1, these numbers shall denote identical or equivalent components of the support rack in the way illustrated above by means of FIG. 1.

The infrared emitter modules 201, 202, 203, 204 are identical in design and emit infrared radiation with a wavelength peak in the range of 1,100 nm to 1,400 nm. The emitter modules 201, 202, 203, 204 have a nominal total power of 12 kW. Each of the emitter modules is configured to have eight cylinder-shaped infrared emitters 205. The infrared emitters 205 are appropriately arranged in the modules 201, 202, 203, 204 such that their emitter tube longitudinal axes extend perpendicular to the support surfaces 108 of the support rack 100.

In FIG. 2, the emitter modules 201, 202, 203, 204 are allocated to the transverse sides 104 of the substrate support elements 101. In an alternative embodiment of the device according to certain exemplary embodiments of the invention (not shown), the emitter modules 201, 202, 203, 204 are allocated to the longitudinal sides 105 of the substrate support elements 101. This is advantageous in that the emitter modules 201, 202, 203, 204 can be provided to have larger dimensions such that a higher irradiation power can be provided.

The corresponding emitter tube of the infrared emitters 205 is made from quartz glass; it has an outer diameter of 14 mm, a wall thickness of 1 mm, and a length of 300 mm. One heating filament made of tungsten each is arranged inside the emitter tube. Moreover, the emitter tube of the infrared emitters 205 includes a side 207 facing the semiconductor disk 206a, 206b to be irradiated, and a side 208 facing away. The side of the emitter tube facing away from the semiconductor disk 206a, 206b is provided with a layer of opaque quartz glass that acts as a reflector.

Referring to the support rack 100, FIG. 2 shows a horizontal section through two substrate support elements 101. Each of the substrate support elements 101 includes two transverse sides 104 and two longitudinal sides 105, whereby the infrared emitter modules 201, 202, 203, 204 are allocated to the transverse sides 104. Due to this arrangement, semiconductor discs that are possibly placed on the support surface 108 are irradiated laterally from two sides. In this type of arrangement of the infrared emitters with respect to the support rack 100, inserted substrates are irradiated, on the one hand, directly by the infrared emitter modules 201, 202, 203, 204. On the other hand, the shelf system is made of carbon, which also takes up radiation energy such that a non-insignificant fraction of the heat input into the substrate takes place by means of the shelf system. In this kind of arrangement, the edges of an inserted substrate are exposed to higher infrared irradiation intensities than the middle of the substrate, as a matter of rule. In order to minimize the resulting differences in substrate temperature, the support surface 108 is made from two composite components, for example, from aluminum and carbon.

Aluminum has a high thermal conductivity of 209 W/(m·K) and is therefore well-suited for rapid dissipation and rapid redistribution of heat energy. In contrast, carbon has a comparably low thermal conductivity of approximately 17 W/(m·K). As a result, the distribution of heat proceeds more slowly in carbon. At the same time, the carbon material has a good heat capacity (0.71 kJ/kg·K at T=20° C.) such that carbon can take up a certain amount of heat itself.

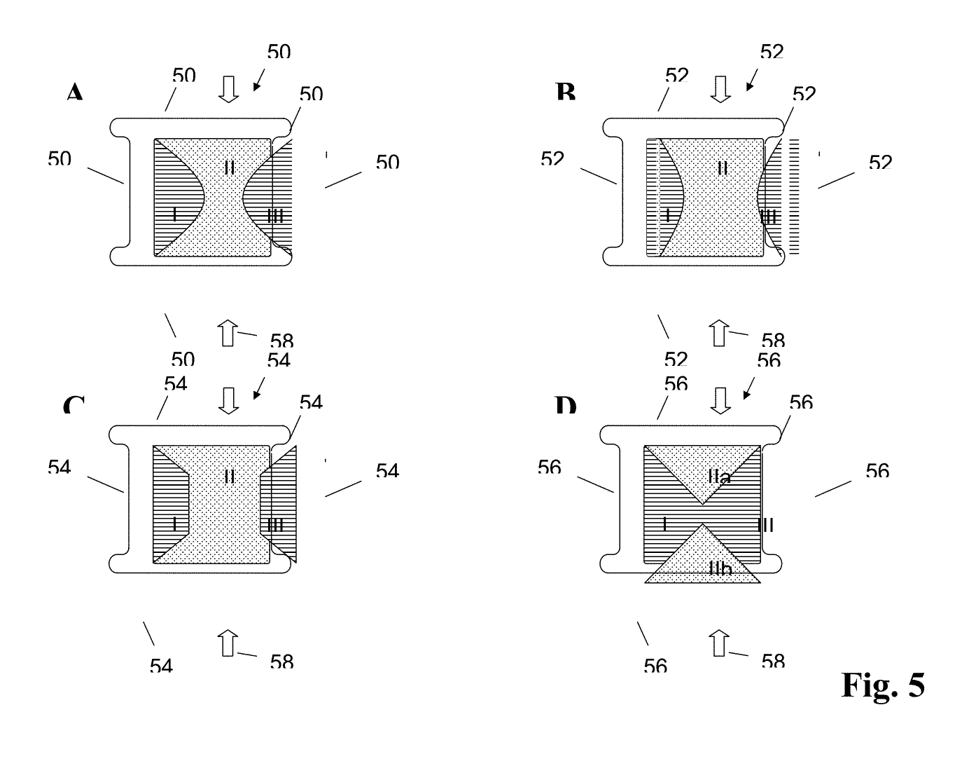

A support surface 108, which is made according to certain exemplary embodiments of the invention from a composite of said aforementioned materials, aluminum and carbon, makes use of these different properties of the composite components. Exemplary refinements of the support surface 108 with respect to the distribution of the composite components are shown in FIG. 5.

A semiconductor disk placed on the support surface 108 is heated, on the one hand, directly by the infrared emitters and, on the other hand, indirectly by the support rack. The direct irradiation of the semiconductor disks with infrared radiation leads to their areas that are allocated to the transverse sides 104 being heated more strongly on average by the infrared emitters than the areas of the semiconductor disks that are allocated to the longitudinal sides 105 and therefore to the longitudinal sides of the support surface. Due to a zone that is made of the first composite component (carbon) and preferably extends along the corresponding transverse side of the support surface being allocated to each of the transverse sides 104, part of the incident irradiation energy is absorbed by the carbon zone of the support surface 108. Due to an intermediate zone made of aluminum being arranged between the carbon zones on the transverse sides 104, rapid heat distribution from the edges of the longitudinal-side support surface to the middle of the aluminum zone is attained such that, in particular, any temperature differences within the substrate are balanced out more rapidly.

Moreover, the masses of the two composite components are selected appropriately such that the heat capacity of the carbon fraction is larger than that of the aluminum fraction. The mass ratio is: 30% aluminum and 70% carbon.

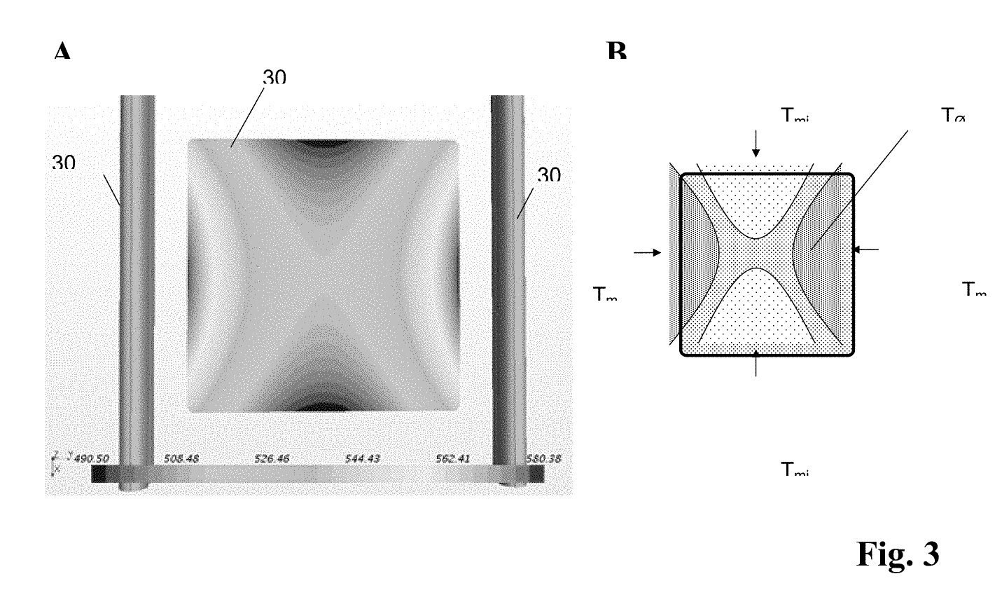

FIG. 3A shows a simulation of the temperature distribution on a silicon substrate 300 after lateral irradiation of the silicon substrate 300 with a nominal power of 28 kW by two infrared modules 301a, 301b. The infrared modules 301a, 301b each include an infrared emitter. The infrared emitter has a cylinder-shaped emitter tube made of quartz glass having an emitter tube length of 1 m. The emitter tube has an oval cross-section of the following external dimensions: 34 mm×14 mm. The wall thickness of the emitter tube is 1.6 mm.

The silicon substrate 300 has a width of 100 mm, a length of 100 mm, and a height of 2 mm. The corners of the silicon substrate 300 are rounded.

The simulation is based on the silicon substrate 300 contacting, by its bottom side, a support element whose support surface is made fully of carbon. The heat transfer to the substrate takes place by two mechanisms, namely by irradiation by infrared radiation and by heat transfer by means of the support element.

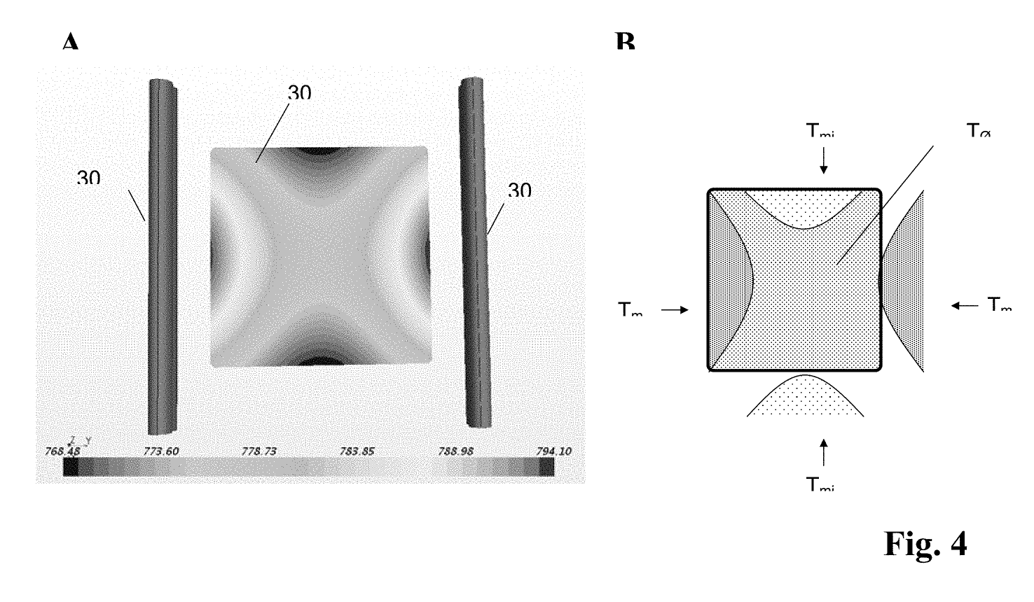

The substrate temperature is in the range of 490.5° C. to 580.38° C. Since FIG. 4 shows both lower and higher temperatures as dark hues and only the transition areas between the minimum and maximum temperatures are shown in bright colours, FIG. 3B shows a simplified schematic depiction of the substrate of FIG. 3A, from which the areas of low, middle and high temperature are easily evident. In the figure, areas of high temperature are hatched darkly, areas of middle temperature are hatched brighter, and areas of low temperature are hatched brightly. The main purpose of FIG. 3B is to illustrate FIG. 3A.

FIG. 4A also shows a simulation of the temperature distribution, like FIG. 3A, with the difference being that the silicon substrate 300 is supported on a support element whose support surface is made from aluminum in the simulation according to FIG. 4A. FIG. 4B serves to illustrate FIG. 4A similar to FIG. 3B explaining FIG. 3A.

FIGS. 3 and 4 show that a support surface being made from a single material can be associated with inhomogeneity in the temperature distribution. In particular, a comparison of FIGS. 3 and 4 shows that a support surface made of carbon is associated with a lower substrate temperature as compared to a support surface made of aluminum [carbon: approx. 540° C.; aluminum: approx. 780° C.].

The substrate temperature being lower can be explained by a substrate support element made of carbon itself having a large heat capacity such that the substrate support element itself takes up part of the heat and such that a lower amount of heat is available for heating the silicon substrate 300.

FIG. 5 shows a top view of four different embodiments of substrate support elements 500, 520, 540, 560 according to certain exemplary embodiments of the invention that can be inserted into the support rack 100 according to FIG. 1. The substrate support elements 500, 520, 540, 560, each include two transverse sides 502, 522, 542, 562 and two longitudinal sides 501, 521, 541, 561. The substrate support elements 500, 520, 540, 560, are designed for use in the device 200 from FIG. 2, whereby one infrared radiation source each is allocated to the transverse sides 502, 522, 542562. The emission direction of the radiation emitted by the infrared radiation sources is indicated by arrows 580.

Moreover, the substrate support elements 500, 520, 540, 560 include a support surface 503, 523, 543, 563 for a substrate that includes two composite components, namely carbon with a thermal conductivity in the range of 0.17 W/(m·K) as first composite component and aluminum with a thermal conductivity of approximately 209 W/(m·K) as second composite component. The support surfaces 503, 523, 543, 563 are subdivided into zones that are manufactured from either the first composite component or the second composite component.

The support surface 503 of the substrate support element 500 according to FIG. 5A includes three zones I, II, III. Zones I and II are manufactured from carbon and zone II is manufactured from aluminum. The shape of zones I and III is identical as each includes a section with a parabolic profile. Zone II is immediately adjacent to zones I, II.

The support surface 523 of the substrate support element 520 (FIG. 5B) differs from the support surface 503 only by the shape of zones I, II, III. Zones I and III also have a section with a parabolic profile—although flattened. Moreover, zone II does not extend fully along the longitudinal side [of the] support surface.

FIG. 5C shows an alternative arrangement of zones I, II, and III from FIG. 5A. Zones I, III are designed to be trapezoidal. Trapezoid zones include straight sections and are therefore easy and inexpensive to manufacture.

In FIG. 5D, the support surface 563 includes four zones I, IIa, IIb, III. The support surface 563 is subdivided into four equal-sized zones I, IIa, IIb, III. Zones I, IIa, IIb, III are shaped like an isosceles triangle. The zone distribution is particularly easy and inexpensive to manufacture.

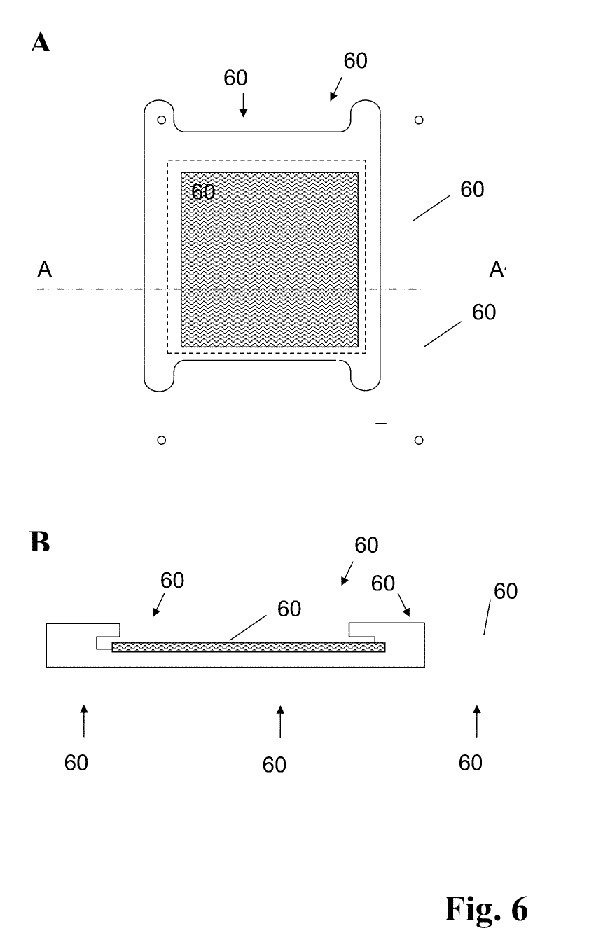

FIG. 6A shows a top view of the top side of a substrate support element according to certain exemplary embodiments of the invention that has reference number 600 allocated to it; FIG. 6B shows a sectional view of the substrate support element 600 along section axis A-A′.

The substrate support element 600 has a support surface 601 in the form of a depression that includes two components that are connected to each other. The first composite component 603 is made from carbon and forms a kind of support frame for the second composite component 602. The second composite component is an aluminum plate that has a length of 120 mm, a width of 120 mm, and a height of 1 mm.

The aluminum plate is inserted, by means of the transverse side 605, into the holders 606 of the first composite component and is connected to same in material-bonded manner. The aluminum plate is dimensioned appropriately such that a substrate that is possibly placed on support surface 601 contacts the aluminum plate exclusively.

If the substrate support element 600 is irradiated laterally with infrared radiation, mainly the edge region 607 of the substrate support element 600 heats up. The edge regions 607 serve as energy stores; the aluminum plate effects an energy transfer from the edge regions 607 into the middle region 608 of the substrate support element. It shows a uniform, homogeneous temperature distribution and thus contributes to a uniform thermal treatment of a substrate that may be placed on the support surface 601.

Although the invention is illustrated and described herein with reference to specific embodiments, the invention is not intended to be limited to the details shown. Rather, various modifications may be made in the details within the scope and range of equivalents of the claims and without departing from the invention.

1. A substrate support element for a support rack for thermal treatment of a substrate, comprising:
a composite body that includes a first composite component and a second composite component, whereby the first composite component has a thermal conductivity in the range of 0.5 to 40 W/(m·K) and the second composite component has a thermal conductivity in the range of 70 to 450 W/(m·K), the composite body including a support surface for the substrate.

2. The substrate support element according to claim 1, wherein the support surface is manufactured from the second composite component, and an edge area of the composite body is manufactured from the first composite component and is adjacent to the support surface.

3. The substrate support element according to claim 1, wherein the support surface includes the first composite component and the second composite component.

4. The substrate support element according to claim 1, wherein the first composite component has a specific heat capacity at 20° C. of at least 0.7 kJ/(kg·K).

5. The substrate support element according to claim 1, wherein a mass of the first composite component and a mass of the second composite component are matched to each other such that a heat capacity of the first composite component is larger than a heat capacity of the second component.

6. The substrate support element according to claim 1 wherein the support surface has a first zone including the first composite component and a second zone including the second composite component.

7. The substrate support element according to claim 6, wherein the first zone includes a section that is oval in shape.

8. The substrate support element according to claim 1, wherein the first composite component is carbon, silicon carbide or blackened zirconium oxide.

9. The substrate support element according to claim 1, wherein the second composite component contains a metal.

10. The substrate support element according to claim 1, wherein the substrate support element is configured to be inserted in a support rack for thermal treatment of a semiconductor disk.

11. A support rack for thermal treatment of a substrate, the support rack comprising:
a first substrate support element, the first substrate support element including a first composite body, the first composite body including a first composite component and a second composite component, whereby the first composite component has a thermal conductivity in the range of 0.5 to 40 W/(m·K) and the second composite component has a thermal conductivity in the range of 70 to 450 W/(m·K), the first composite body including a first substrate support surface: and
a second substrate support element, the second substrate support element including a second composite body, the second composite body including a third composite component and a fourth composite component, whereby the third composite component has a thermal conductivity in the range of 0.5 to 40 W/(m·K) and the fourth composite component has a thermal conductivity in the range of 70 to 450 W/(m·K), the second composite body including a second substrate support surface,
whereby the first substrate support element and the second substrate support element are arranged such that the first substrate support surface and the second substrate extend parallel with respect to each other.

12. A device for irradiation of a substrate, the device comprising:
at least one substrate support element, the at least one substrate support element including a composite body, the composite body including a first composite component a second composite component, whereby the first composite component has a thermal conductivity in the range of 0.5 to 40 W/(m·K) and the second composite component has a thermal conductivity in the range of 70 to 450 W/(m·K), the composite body including a support surface for the substrate; and
at least one infrared emitter for irradiation of the at least one substrate support element.

13. The device according to claim 12, wherein the support surface of the substrate support element has a first zone including the first composite component and a second zone including the second composite component, the support surface including a transverse side facing the infrared emitter as well as two longitudinal sides, whereby the first zone extends along the transverse side.

14. The device according to claim 13, wherein the second zone extends along at least one of the longitudinal sides.

15. The substrate support element according to claim 2, wherein the first composite component has a specific heat capacity at 20° C. of at least 0.7 kJ/(kg·K).

16. The substrate support element according to claim 3, wherein the first composite component has a specific heat capacity at 20° C. of at least 0.7 kJ/(kg·K).

17. The substrate support element according to claim 1, wherein the first composite component has a specific heat capacity at 20° C. in the range of 0.7 kJ/(kg·K) to 1.0 kJ/(kg·K).

18. The substrate support element according to claim 2, wherein the first composite component has a specific heat capacity at 20° C. in the range of 0.7 kJ/(kg·K) to 1.0 kJ/(kg·K).

19. The substrate support element according to claim 3, wherein the first composite component has a specific heat capacity at 20° C. in the range of 0.7 kJ/(kg·K) to 1.0 kJ/(kg·K).

20. The substrate support element according to claim 2, wherein a mass of the first composite component and the mass of the second composite component are matched to each other such that a heat capacity of the first composite component is larger than a heat capacity of the second composite component.
